(19) United States
(12) Patent Application Publication
(10) Pub. No.: US 2024/0112917 A1
(43) Pub. Date: Apr. 4, 2024

(54) METHOD FOR PROCESSING SUBSTRATE, AND METHOD FOR MANUFACTURING SILICON DEVICE COMPRISING SAID PROCESSING METHOD

(71) Applicant: TOKUYAMA CORPORATION, Yamaguchi (JP)

(72) Inventors: Yoshiki SEIKE, Yamaguchi (JP); Manami OSHIO, Yamaguchi (JP); Naoto NOMURA, Yamaguchi (JP); Kohsuke NORO, Yamaguchi (JP); Seiji TONO, Yamaguchi (JP)

(73) Assignee: TOKUYAMA CORPORATION, Yamaguchi (JP)

(21) Appl. No.: 18/274,856

(22) PCT Filed: Feb. 8, 2022
(86) PCT No.: PCT/JP2022/004803

§ 371 Date: Jul. 28, 2023

(30) Foreign Application Priority Data
Feb. 10, 2021 (JP) 2021-020010
Jun. 18, 2021 (JP) 2021-102055
Aug. 30, 2021 (JP) 2021-140036

(51) Int. Cl. H01L 21/306; C09K 13/00

(52) U.S. Cl. CPC H01L 21/30604; C09K 13/00

(57) ABSTRACT

[Problem to be solved] Provided is a method for processing a substrate having high etching selectivity of silicon with respect to silicon-germanium and further having a high selection ratio of silicon with respect to a silicon oxide film and/or a silicon nitride film in surface processing when manufacturing various types of silicon devices, particularly various types of silicon composite semiconductor devices containing silicon-germanium.

[Solution] A method for processing a substrate includes: bringing an etching solution into contact with a substrate including a silicon film and a silicon-germanium film to perform etching; and selectively removing the silicon film, in which the etching solution contains an organic alkali and water and has a dissolved oxygen concentration of 0.20 ppm or less.

### TECHNICAL FIELD

The present invention relates to a method for processing a substrate, and more particularly relates to a method for selectively removing a silicon film from a substrate including the silicon film and a silicon-germanium film. In addition, the present invention relates to a method for manufacturing a silicon device including the processing method. The substrate includes a semiconductor wafer, a silicon substrate, and the like.

### BACKGROUND ART

In a process for manufacturing a semiconductor device, silicon etching is used in various steps. In recent years, the silicon etching is applied to producing a structure called a fin field-effect transistor (Fin-FET) or gate all around (GAA), and is essential for stacking of memory cells and three-dimensionalization of a logic device. Due to densification of a device, a stricter requirement is imposed on a silicon etching technique used here regarding smoothness of a wafer surface after etching, an etching accuracy, etching selectivity with respect to other materials, and the like. In addition, the etching technique is also applied to a process such as thinning of a silicon wafer. Such various types of silicon devices are required to be highly integrated, miniaturized, highly sensitive, and highly functional depending on applications thereof, and in order to satisfy these requirements, the silicon etching is considered important as a fine processing technique in manufacturing the silicon devices.

In particular, various methods for producing a silicon composite semiconductor device using silicon-germanium are increased, and the etching technique may be used for manufacturing nanowires using the above GAA structure. For example, a silicon film and a silicon-germanium film are alternately formed by epitaxial growth, and then etching is performed using only the silicon film as a sacrificial layer, whereby the silicon-germanium film can be left as a channel layer. At this time, an etching characteristic capable of uniformly removing only silicon without dissolving silicon-germanium is important.

Here, examples of the silicon etching include etching using a fluoric acid-nitric acid aqueous solution and etching using an alkali. The etching using a fluoric acid-nitric acid aqueous solution can be performed isotropically regardless of a crystal orientation of silicon, and can uniformly etch single crystal silicon, polysilicon, and amorphous silicon. However, the fluoric acid-nitric acid aqueous solution oxidizes silicon and etches silicon as a silicon oxide film, and thus has no selection ratio with respect to the silicon oxide film. Therefore, the fluoric acid-nitric acid aqueous solution cannot be used in a semiconductor manufacturing process or the like in which a silicon oxide film should remain. In addition, the fluoric acid-nitric acid aqueous solution also dissolves silicon-germanium, and thus cannot be used in the semiconductor manufacturing process in which the silicon-germanium film should remain.

In a case of the silicon etching using an alkali, the alkali has a feature that it not only has high etching selectivity of silicon with respect to a silicon nitride film, but also has high etching selectivity of silicon with respect to a silicon oxide film. Therefore, the silicon etching using an alkali can be used in a semiconductor manufacturing process in which the silicon oxide film or the silicon nitride film should remain. Here, the high selectivity means a property of exhibiting a particularly high etching property of silicon with respect to a specific member. For example, when etching a substrate having a silicon film of single crystal silicon, polysilicon, or amorphous silicon and another film (for example, a silicon oxide film), in a case of only etching the silicon film and not etching the silicon oxide film, etching selectivity of silicon with respect to the silicon oxide film is high. An alkaline etching solution has a high etching selectivity of silicon with respect to the silicon oxide film and the silicon nitride film, and selectively etches the silicon film. In a case of the alkaline etching solution, though an etching rate of silicon-germanium is lower than that for silicon, selectivity is not sufficient, the etching of the silicon-germanium film is not prevented sufficiently, and it is not possible to only etch silicon.

As the alkaline etching solution described above, an aqueous solution of a general alkaline chemical such as KOH, hydrazines, or tetramethylammonium hydroxide (hereinafter also referred to as TMAH) can be used (see Patent Literatures 1 and 2). Among these, KOH and TMAH, which have low toxicity and are easy to handle, are suitably used alone. Among these, TMAH is more suitably used in consideration of low contamination of a metal impurity and the etching selectivity with respect to the silicon oxide film.

Regarding the etching using an alkali, Patent Literature 1 discloses an etching solution for a solar cell silicon substrate, which contains an alkali hydroxide, water, and a polyalkylene oxide alkyl ether. Patent Literature 2 discloses an etching solution for a solar cell silicon substrate, which contains an alkaline compound, an organic solvent, a surfactant, and water. In Patent Literature 2, an example of the alkaline compound is TMAH, but the alkaline compound actually used is sodium hydroxide or potassium hydroxide. Patent Literature 3 discloses a chemical solution in which an organic alkaline compound and a reducing compound are mixed. Patent Literature 4 discloses a solution in which a surfactant and a corrosion inhibitor are optionally mixed with water, an organic alkali, and a water-miscible solvent.

### CITATION LIST

### Patent Literature

Patent Literature 1: Japanese Patent Laid-Open No. 2010-141139
Patent Literature 2: Japanese Patent Laid-Open No. 2012-227304
Patent Literature 3: Japanese Patent Laid-Open No. 2006-054363
Patent Literature 4: Japanese Patent Laid-Open No. 2019-50364

### SUMMARY OF INVENTION

### Technical Problem

In the etching solutions according to Patent Literatures 1 and 2, NaOH and KOH are used as the alkaline compound. As described above, the etching using an alkali has a higher selectivity of silicon with respect to the silicon oxide film than the fluoric acid-nitric acid aqueous solution, but an alkali metal hydroxide has a higher etching rate of the silicon oxide film than a quaternary ammonium hydroxide. Therefore, in the etching of the silicon film, when a silicon oxide film is used for a part of a mask material and a part of a pattern structure, the silicon oxide film to be remain is also etched in the processing for a long time during the silicon etching. In addition, there is a disadvantage that it is not possible to selectively only etch the silicon film without etching the silicon oxide film despite a reduced allowable etching amount of the oxide film due to miniaturization. An etching solution according to Patent Literature 3 is intended to improve an etching rate more than that of an organic alkali simple substance, and is not expected at all to be used for a purpose of selectively removing silicon with respect to silicon-germanium. An etching solution described in Patent Literature 4 is a chemical solution capable of selectively removing silicon with respect to silicon-germanium, but etching selectivity of silicon with respect to silicon-germanium is not sufficient.

Therefore, an object of the present invention is to provide a method for processing a substrate having high etching selectivity of silicon with respect to silicon-germanium and further having a high selection ratio with respect to a silicon oxide film and/or a silicon nitride film in surface processing when manufacturing various types of silicon devices, particularly various types of silicon composite semiconductor devices containing silicon-germanium.

### Solution to Problem

As a result of diligent efforts, the present inventors have found that the above problem can be solved by using an “etching solution composed of a solution containing an organic alkali and water (hereinafter also referred to as an organic alkaline aqueous solution) in which a dissolved oxygen concentration is lowered. The organic alkaline aqueous solution can be used to perform etching with high selectivity of silicon with respect to the silicon oxide film and the silicon nitride film, and can increase an etching selection ratio of silicon with respect to silicon-germanium by lowering the dissolved oxygen concentration. Further, the present inventors have found that the dissolved oxygen concentration can be easily lowered by containing a reducing compound in the organic alkaline aqueous solution.

That is, the present invention for solving the above problem includes the following subject matters.
(1) A method for processing a substrate including:
   bringing an etching solution into contact with a substrate including a silicon film and a silicon-germanium film to perform etching; and
   selectively removing the silicon film, in which
   the etching solution contains an organic alkali and water and has a dissolved oxygen concentration of 0.20 ppm or less.
(2) The method for processing a substrate according to (1), in which the etching solution contains a reducing compound.
(3) The method for processing a substrate according to (2), in which the reducing compound is at least one selected from the group consisting of hydrazines, hydroxylamines, a reducing sugar, and gallic acid.
(4) The method for processing a substrate according to (2), in which the reducing compound is a reducing sugar having no hydroxy group on 2-position carbon.
(5) The method for processing a substrate according to (1), in which a concentration of the organic alkali contained in the etching solution is 0.05 mol/L to 2.2 mol/L.
(6) A method for manufacturing a silicon device including: the method for processing a substrate according to any one of (1) to (5) described above.

### Advantageous Effects of Invention

According to the method for processing a substrate in the present invention, a silicon film can be selectively removed with high accuracy from a substrate including the silicon film and a silicon-germanium film. In addition, since appropriate processing can be performed even when an organic alkali concentration is low, toxicity and a cost of waste liquid processing can be reduced.

Further, when the etching solution contains a polyhydroxy compound or a quaternary ammonium salt, it is possible to prevent occurrence of a pyramid-shaped hillock surrounded by a (111) plane on a silicon surface (100 plane) and to smoothly etch the silicon surface.

Further, by using, as the reducing compound, a reducing sugar having no hydroxy group on 2-position carbon, an etching rate of silicon is stable over time, and thus an etching solution that can be applied to an application of etching the silicon film with high accuracy is provided.

### DESCRIPTION OF EMBODIMENTS

As described above, according to a method for processing a substrate in the present invention, an etching solution is brought into contact with a substrate including a silicon film and a silicon-germanium film to perform etching and the silicon film is selectively removed. Here, the silicon film is a silicon single crystal, polysilicon, or amorphous silicon, but is not limited thereto. In order to improve a performance of a semiconductor, a film using silicon doped with impurities such as boron and phosphorus is also included in the silicon film. The silicon-germanium film is a mixed film containing silicon and germanium, and refers to one having a germanium content of 1% or more, and preferably 5% to 50%.

The processing method according to the present invention is characterized in that an etching solution containing an organic alkali and water and having a dissolved oxygen concentration of 0.20 ppm or less is used as the etching solution. First, the etching solution used in the processing method according to the present invention will be described.

(Etching Solution)

The etching solution used in the processing method according to the present invention is characterized by containing an organic alkali and water and having a dissolved oxygen concentration of 0.20 ppm or less.

(Organic Alkali)

As the organic alkali, various organic alkalis used for silicon etching are used. In view of high selectivity of the silicon film, preferably used is at least one organic alkali selected from the group consisting of a quaternary ammonium hydroxide represented by the following Formula (1), an amine represented by the following Formula (2), an amine represented by the following Formula (3), a cyclic amine represented by the following Formula (4), 1,8-diazabicyclo[5.4.0]undec-7-ene, and 1,5-diazabicyclo[4.3.0]non-5-ene, and particularly preferably used is a quaternary ammonium hydroxide or an amine.

R¹¹R¹²R¹³R¹⁴N⁺·OH⁻ (1)

In the formula, R¹¹, R¹², R¹³ and R¹⁴ each independently represent an alkyl group having 1 to 16 carbon atoms and an aryl group, or a benzyl group, and the alkyl group, the aryl group or the benzyl group may have a hydroxy group.

The alkyl group is preferably an alkyl group having 1 to 16 carbon atoms, and more preferably an alkyl group having 1 to 4 carbon atoms. The aryl group is preferably an aryl group having 6 to 10 carbon atoms.

The alkyl group, the aryl group and the benzyl group may have a hydroxy group as a substituent.

Examples of R¹¹, R¹², R¹³, and R¹⁴ include: an unsubstituted alkyl group having 1 to 4 carbon atoms such as methyl group, ethyl group, n-propyl group, i-propyl group, n-butyl group, i-butyl group, sec-butyl group, and tert-butyl group; a hydroxy group-substituted alkyl group having 1 to 4 carbon atoms such as hydroxymethyl group, hydroxyethyl group, hydroxy-n-propyl group, hydroxy-i-propyl group, hydroxy-n-butyl group, hydroxy-i-butyl group, hydroxy-sec-butyl group, and hydroxy-tert-butyl group; phenyl group; and benzyl group.

The total number of carbon atoms in R¹¹, R¹², R¹³ and R¹⁴ is preferably 20 or less from the viewpoint of solubility, and R¹¹, R¹², R¹³ and R¹⁴ are each preferably an alkyl group having 1 to 4 carbon atoms or a hydroxy group-substituted alkyl group having 1 to 4 carbon atoms, and more preferably, at least three of R¹¹, R¹², R¹³ and R¹⁴ are the same alkyl group. The alkyl group having 1 to 4 carbon atoms is preferably methyl group, ethyl group, propyl group, butyl group, isobutyl group, or hydroxyethyl group, and the alkyl group being the same for at least three of R¹¹, R¹², R¹³, and R¹⁴ is preferably trimethyl, triethyl, or tributyl.

Preferable examples of the quaternary ammonium hydroxide represented by Formula (1) include tetramethylammonium hydroxide (TMAH), tetraethylammonium hydroxide (TEAH), ethyltrimethylammonium hydroxide (ETMAH), tetrapropylammonium hydroxide (TPAH), tetrabutylammonium hydroxide (TBAH), trimethyl-2-hydroxyethylammonium hydroxide (choline hydroxide), dimethylbis(2-hydroxyethyl)ammonium hydroxide, and methyltris(2-hydroxyethyl)ammonium hydroxide.

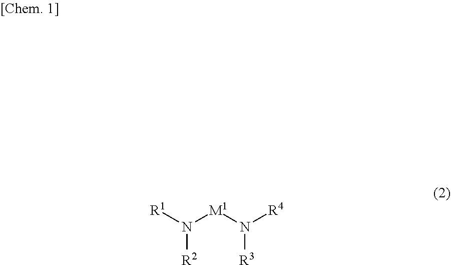

In the formula, R¹ to R⁴ each independently represent a hydrogen atom or a methyl group, M¹ represents a divalent non-cyclic aliphatic hydrocarbon group or a divalent group in which a part of carbon atoms of a main chain of the divalent non-cyclic aliphatic hydrocarbon group is substituted with a nitrogen atom, and these groups may have an imino group as a substituent. Further, the total number of carbon atoms and nitrogen atoms in R¹ to R⁴ and M¹ is 4 to 20.

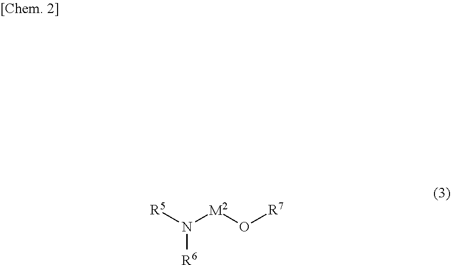

In the formula, R⁵ to R⁷ each independently represent a hydrogen atom or a methyl group, and M² is a divalent non-cyclic aliphatic hydrocarbon group or a divalent group in which a part of carbon atoms of a main chain of the divalent non-cyclic aliphatic hydrocarbon group is substituted with a nitrogen atom or an oxygen atom. Further, the total number of carbon atoms, nitrogen atoms, and oxygen atoms in R⁵ to R⁷ and M² is 4 to 20.

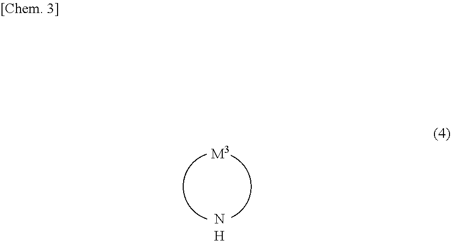

In the formula, M³ is an alkylene group having 2 to 8 carbon atoms.

As the organic alkali, 1,8-diazabicyclo[5.4.0]undec-7-ene and 1,5-diazabicyclo[4.3.0]non-5-ene can also be used.

In Formula (2), when M¹ is composed of only carbon atoms, the total number of the carbon atoms in R¹ to R⁴ and M¹ is preferably 4 to 10 from the viewpoint of excellent etching selectivity of silicon with respect to silicon-germanium and the viewpoint of the solubility. Further, M¹ is more preferably an alkylene group having 4 to 10 carbon atoms.

In Formula (2), when M¹ contains a nitrogen atom, the total number of the carbon atoms and nitrogen atoms in R¹ to R⁴ and M¹ is preferably 6 to 16 from the viewpoint of the excellent etching selectivity of silicon with respect to silicon-germanium and the viewpoint of the solubility.

In Formula (2), M¹ is more preferably a group represented by Formula (5),

—C(═NH)— (5)

a group represented by Formula (6),

—(CH₂)_{L}—NR⁸—(CH₂)_{L}— (6)

(in the formula, R⁸ represents a hydrogen atom or methyl group, and L represents an integer of 3 to 6) or a group represented by Formula (7),

—(CH₂)ₘ—NR⁹—(CH₂)ₙ—NR¹⁰—(CH₂)ₘ— (7)

(in the formula, R⁹ and R¹⁰ each independently represents a hydrogen atom or methyl group, m represents an integer of 2 to 4, and n represents an integer of 3 to 4).

Preferable examples of the amine represented by Formula (2) include 1,4-diaminobutane, 1,5-diaminopentane, 1,6-diaminohexane, 1,7-diaminoheptane, 1,8-diaminooctane, 1,1,3,3-tetramethylguanidine, dipropylenetriamine, bis(hexamethylene)triamine, N,N,N-trimethyldiethylenetriamine, and N,N-bis(3-aminopropyl)ethylenediamine.

In Formula (3), the total number of the carbon atoms, nitrogen atoms, and oxygen atoms in R⁵ to R⁷ and M² is preferably 4 to 20 from the viewpoint of further improving the etching selectivity of silicon with respect to silicon-germanium, and is more preferably 4 to 10 from the viewpoint of the solubility.

Preferable examples of the amine represented by Formula (3) include 2-(2-aminoethoxy)ethanol, 2-amino-2-methyl-1-propanol, 4-amino-i-butanol, 5-amino-1-pentanol, 6-amino-1-hexanol, N-(2-aminoethyl)propanolamine, 2-(dimethylamino)ethanol, N-(2-hydroxypropyl)ethylenediamine, and 4-dimethylamino-1-butanol.

In Formula (4), M³ is preferably an alkylene group having 2 to 8 carbon atoms, and more preferably 4 to 8 carbon atoms from the viewpoint of further improving the etching selectivity of silicon with respect to silicon-germanium.

Preferable examples of the cyclic amine represented by Formula (4) include azetidine, pyrrolidine, piperidine, hexamethyleneimine, pentamethyleneimine, and octamethyleneimine.

Among the above organic alkalis, from the viewpoint of preventing occurrence of a pyramid-shaped hillock surrounded by a (111) plane on a silicon surface and reducing occurrence of roughness on the silicon surface, the quaternary ammonium hydroxide represented by Formula (1), the amine represented by Formula (2), the cyclic amine represented by Formula (4), 1,8-diazabicyclo[5.4.0]undec-7-ene, and 1,5-diazabicyclo[4.3.0]non-5-ene are more preferable. Regarding the quaternary ammonium hydroxides represented by Formula (1), tetrapropylammonium hydroxide (TPAH) is particularly preferable. Regarding the amine represented by Formula (2), 1,4-diaminobutane, 1,5-diaminopentane, 1,6-diaminohexane, 1,7-diaminoheptane, 1,8-diaminooctane, 1,1,3,3-tetramethylguanidine, dipropylenetriamine, bis(hexamethylene)triamine, N,N,N-trimethyldiethylenetriamine, and N,N-bis(3-aminopropyl)ethylenediamine are particularly preferable. Preferable examples of the amine represented by Formula (4) particularly include pyrrolidine, piperidine, hexamethyleneimine, pentamethyleneimine, and octamethyleneimine.

The organic alkali is preferably the quaternary ammonium hydroxide represented by Formula (1) from the viewpoint of having a stable structure and hardly causing decomposition by a side reaction. Specifically, preferable examples of the quaternary ammonium hydroxide include tetramethylammonium hydroxide (TMAH), tetraethylammonium hydroxide (TEAH), ethyltrimethylammonium hydroxide (ETMAH), tetrapropylammonium hydroxide (TPAH), and tetrabutylammonium hydroxide (TBAH). From the viewpoint of further improving the etching selectivity of silicon with respect to silicon-germanium, the amine represented by Formula (2), the cyclic amine represented by Formula (4), 1,8-diazabicyclo[5.4.0]undec-7-ene, and 1,5-diazabicyclo[4.3.0]non-5-ene are more preferable. Specifically, preferable examples thereof include 1,4-diaminobutane, 1,5-diaminopentane, 1,6-diaminohexane, 1,7-diaminoheptane, 1,8-diaminooctane, 1,1,3,3-tetramethylguanidine, dipropylenetriamine, bis(hexamethylene)triamine, N,N,N-trimethyldiethylenetriamine, N,N-bis(3-aminopropyl)ethylenediamine, pyrrolidine, piperidine, hexamethyleneimine, pentamethyleneimine, octamethyleneimine, 1,8-diazabicyclo[5.4.0]undec-7-ene, and 1,5-diazabicyclo[4.3.0]non-5-ene.

A concentration of the organic alkali is not particularly different from that in conventionally known etching solution. When the concentration is in a range of 0.05 mol/L to 2.2 mol/L, the solubility is good, and an excellent etching effect is obtained.

One kind of organic alkali may be used alone, or a plurality of different kinds of organic alkalis may be mixed and used.

(Water)

The etching solution contains water. The water to be used is preferably deionized water or ultrapure water in which amounts of various impurities are reduced.

(Dissolved Oxygen Concentration)

The etching solution used in the processing method according to the present invention has a dissolved oxygen concentration of 0.20 ppm or less. When the dissolved oxygen concentration exceeds 0.20 ppm, sufficient etching selectivity of silicon with respect to silicon-germanium cannot be obtained. For example, when the dissolved oxygen concentration is 0.20 ppm or less, an etching selection ratio of silicon with respect to silicon-germanium can be approximately 70 or more. The dissolved oxygen amount is a value measured by a fluorescence method.

Since an etching rate of silicon-germanium is reduced and the etching selectivity of silicon with respect to silicon-germanium is further improved, the dissolved oxygen concentration in the etching solution is preferably 0.10 ppm or less, and more preferably 0.05 ppm or less. The silicon etching selection ratio of the etching solution with respect to silicon-germanium is preferably 70 or more, more preferably 90 or more, still more preferably 100 or more, particularly preferably 300 or more, and most preferably 400 or more.

(Reducing Compound)

The etching solution used in the processing method according to the present invention may contain a reducing compound. By containing the reducing compound, the dissolved oxygen concentration in the etching solution can be easily decreased to 0.20 ppm or less, and thus silicon can be selectively removed with respect to silicon-germanium.

The reducing compound is preferably an organic substance from the viewpoint of preventing contamination of a metal impurity.

Specific examples of the reducing compound to be suitably used include hydrazines, hydroxylamines, phosphates, hypophosphites, a reducing sugar, quinones, ketoximes, gallic acid, and thioglycerol. More specifically, examples of the hydrazines include hydrazine, methyl hydrazine, carbohydrazide, methyl hydrazine sulfate, hydrazine monohydrochloride, hydrazine dihydrochloride, hydrazine sulfate, hydrazine carbonate, hydrazine dihydrobromide, and hydrazine phosphate; examples of the hydroxylamines include hydroxylamine, dimethylhydroxylamine, diethylhydroxylamine, hydroxylamine sulfate, hydroxylamine chloride, hydroxylamine oxalate, hydroxylamine phosphate, and hydroxylamine-o-sulfonic acid; examples of the phosphates include ammonium dihydrogen phosphate; examples of the hypophosphites include ammonium hypophosphite; examples of the reducing sugar include glyceraldehyde, erythrose, threose, ribose, arabinose, xylose, lyxose, glucose, mannose, galactose, allose, altrose, gulose, idose, fructose, psicose, sorbose, tagatose, xylulose, ribulose, maltose, lactose, lactulose, cellobiose, melibiose, isomaltooligosaccharide, fructooligosaccharide, and galactooligosaccharide; examples of the quinones include pyrocatechol, hydroquinone, benzoquinone, aminophenol, and p-methoxyphenol; examples of the ketoximes include methyl ethyl ketoxime and dimethylketoxime; gallic acid; and thioglycerol. Hydrazines, hydroxylamines, a reducing sugar, and gallic acid are more preferable. Specifically, as the hydrazines, hydrazine, methyl hydrazine, carbohydrazide, methyl hydrazine sulfate, hydrazine monohydrochloride, hydrazine dihydrochloride, hydrazine sulfate, hydrazine carbonate, hydrazine dihydrobromide, and hydrazine phosphate are preferable; as the hydroxylamines, hydroxylamine, dimethylhydroxylamine, diethylhydroxylamine, hydroxylamine sulfate, hydroxylamine chloride, and hydroxylamine oxalate are preferable; as the reducing sugar, glyceraldehyde, erythrose, threose, ribose, arabinose, xylose, lyxose, glucose, mannose, galactose, allose, altrose, gulose, idose, fructose, psicose, sorbose, tagatose, xylulose, ribulose, maltose, lactose, lactulose, cellobiose, melibiose, isomaltooligosaccharide, fructooligosaccharide, and galactooligosaccharide are preferable; and gallic acid is preferable. The reducing sugar is still more preferable. Specifically, erythrose, threose, ribose, arabinose, glucose, fructose, galactose, maltose, lactose, cellobiose, isomaltooligosaccharide, and galactooligosaccharide are preferable.

The reducing sugar is a sugar that forms an aldehyde group (formyl group) or a ketone group (ketonic carbonyl group) in an alkaline aqueous solution, the aldehyde group exhibits reducibility, and in the reducing sugar, ketone can be isomerized into an aldehyde, and thus exhibits the reducibility. The reducibility is considered to remove dissolved oxygen in the etching solution and provide a stable etching selection ratio. It is presumed that a reason why it must be a reducing sugar not just any aldehyde is that since the sugar is in an equilibrium state between a cyclic structure and a chain structure in a solution, the aldehyde is supplied (ring-opened) by a consumed amount, and thus a certain concentration of the aldehyde can be present for a long time.

In the sugar, 2-position carbon is ring-forming carbon located adjacent to carbon (1-position carbon) serving as carbonyl carbon at the time of ring-opening when the sugar has a cyclic structure. Accordingly, when a ring-opening structure (chain structure) is formed in the solution and the like, the 2-position carbon is located at the α-position of the carbonyl group. All of the reducing sugars described above are compounds having a hydroxy group on the 2-position carbon, and in the present invention, the above reducing sugars can also be used.

In addition, as the reducing sugar, a reducing sugar having no hydroxy group on the 2-position carbon can also be used. As such a reducing sugar, for example, deoxy sugars in which a hydroxy group on the 2-position carbon is substituted with hydrogen, amino sugars in which a hydroxy group on the 2-position carbon is substituted with an amino group, sugars in which an amino group is acylated, and sugars in which a hydroxy group is alkylated into an alkoxy group can be used.

Specific examples of the reducing sugar having no hydroxy group on the 2-position carbon include 2-deoxyribose, 2-deoxyglucose, glucosamine, galactosamine, lactosamine, mannosamine, N-acetylglucosamine, N-benzoylglucosamine, N-hexanoylglucosamine, N-acetylgalactosamine, N-acetyllactosamine, and N-acetylmannosamine.

The reducing sugars having no hydroxy group on the 2-position carbon specifically listed above are each a compound in which only the hydroxy group on the 2-position carbon is substituted. In the present invention, as the reducing sugar, a compound in which the hydroxy group on another carbon is also substituted with another group can also be used. However, it should be noted that since the hydroxy group bonded to a 1-position carbon atom in a case of the cyclic structure corresponds to an oxygen atom of the carbonyl group in a case of the chain structure, the sugar is not a reducing sugar when the hydroxy group does not remain as it is. When a hydroxymethyl group is bonded to the same carbon, the sugar is a ketone type in the case of the chain structure, and the hydroxymethyl group is involved in isomerizing to an aldehyde type, and thus the sugar does not become a reducing sugar when the hydroxy group does not remain as it is.

When the reducing sugar having no hydroxy group on the 2-position carbon is used as the reducing compound in the silicon etching solution, an advantage of using the reducing compound can be obtained, and stability over time during storage or continuous use can be improved. Therefore, when the etching solution containing the reducing sugar having no hydroxy group on the 2-position carbon is used as the reducing compound, a silicon device can be manufactured with higher productivity. Since the etching solution containing the reducing sugar having no hydroxy group on the 2-position carbon is less likely to undergo a change over time in the etching rate of silicon, the etching solution can be applied to an application of etching the silicon film with high accuracy in addition to selective etching of the silicon film from a substrate having the silicon film and a silicon-germanium film.

That is, according to another aspect of the present invention, there is provided an etching solution containing an organic alkali, a reducing sugar, and water, in which the reducing sugar is a reducing sugar having no hydroxy group on 2-position carbon.

One kind of the reducing compound may be used alone or two or more kinds may be used in combination. A concentration of the reducing compound is preferably 0.01 mass % to 50 mass %, and more preferably 0.1 mass % to 30 mass %.

When the reducing sugar having no hydroxy group on the 2-position carbon is used in the etching solution, a content thereof is preferably 0.01 mass % to 30 mass %, and more preferably 0.1 mass % to 15 mass %.

(Other Components)

The etching solution may further contain a polyhydroxy compound having 2 to 12 carbon atoms and having two or more hydroxy groups in a molecule (hereinafter, also simply referred to as a polyhydroxy compound). However, the polyhydroxy compound needs to be a compound which does not correspond to the reducing compound suitably used in the present invention, and more specifically, the polyhydroxy compound does not contain quinones, a reducing sugar, gallic acid, and thioglycerol. By containing the polyhydroxy compound, the occurrence of the pyramid-shaped hillock surrounded by the (111) plane on the silicon surface can be prevented, and the silicon surface can be etched smoothly without any roughness on the silicon surface.

In the polyhydroxy compound, the number of carbon atoms is 2 to 12, and preferably 2 to 6.

A ratio (OH/C) of the number of hydroxy groups to the number of carbon atoms in a molecule of the polyhydroxy compound is preferably 0.3 or more and 1.0 or less, more preferably 0.4 or more and 1.0 or less, and still more preferably 0.5 or more and 1.0 or less, from viewpoints that hydration due to hydrogen bonding between the hydroxy groups and water progresses and the number of free water molecules that contributes to the reaction is reduced to smoothly etch the silicon.

Specific examples of the polyhydroxy compound suitably used include ethylene glycol, propylene glycol, 1,3-propanediol, 1,2-butanediol, 1,3-butanediol, 1,4-butanediol, 1,5-pentanediol, 1,2-hexanediol, 1,6-hexanediol, hexylene glycol, cyclohexanediol, pinacol, glycerin, trimethylolpropane, erythritol, pentaerythritol, dipentaerythritol, xylitol, dulcitol, mannitol, and diglycerin. Among these, ethylene glycol, propylene glycol, 1,3-propanediol, 1,2-butanediol, 1,3-butanediol, 1,4-butanediol, glycerin, trimethylolpropane, erythritol, pentaerythritol, dipentaerythritol, xylitol, dulcitol, mannitol, or diglycerin is preferable, and particularly, ethylene glycol, glycerin, xylitol, or diglycerin is more preferable.

A higher concentration of the polyhydroxy compound reduces the occurrence of the pyramidal hillock surrounded by the (111) plane of the silicon surface, and the silicon surface can be etched more smoothly without any roughness. When the polyhydroxy compound is used, the concentration thereof is preferably 20 mass % or more and 80 mass % or less, more preferably 40 mass % or more and 80 mass % or less, and still more preferably 60 mass % or more and 80 mass % or less based on a total mass of the entire etching solution.

One kind of the polyhydroxy compound may be used alone, or a plurality of different kinds of polyhydroxy compounds may be mixed and used.

The silicon etching solution may further contain a quaternary ammonium salt represented by the following Formula (8).

R¹¹¹R¹¹²R¹¹³R¹¹⁴N⁺·X⁻ (8)

(In the formula, R¹¹¹, R¹¹², R¹¹³ and R¹¹⁴ each represent an alkyl group having 1 to 16 carbon atoms which may have a substituent, and may be the same group or different groups. X represents BF₄, a fluorine atom, a chlorine atom, or a bromine atom.)

By containing the quaternary ammonium salt represented by Formula (8), the occurrence of the pyramid-shaped hillock surrounded by the (111) plane on the silicon surface can be further prevented, and the silicon surface can be etched more smoothly without any roughness.

In the quaternary ammonium salt represented by Formula (8), R¹¹¹, R¹¹², R¹¹³, and R¹¹⁴ each represent an alkyl group having 1 to 16 carbon atoms which may have a substituent, and may be the same group or different groups. X represents BF₄, a fluorine atom, a chlorine atom, or a bromine atom.

The alkyl group may have a hydroxy group as the substituent.

Examples of R¹¹¹, R¹¹², R¹¹³, and R¹¹⁴ include: an unsubstituted alkyl group having 1 to 16 carbon atoms such as methyl group, ethyl group, n-propyl group, i-propyl group, n-butyl group, i-butyl group, sec-butyl group, tert-butyl group, hexyl group, octyl group, decyl group, dodecyl group, tetradecyl group, and hexadecyl group; and a hydroxy group-substituted alkyl group having 1 to 4 carbon atoms such as hydroxymethyl group, hydroxyethyl group, hydroxy-n-propyl group, hydroxy-i-propyl group, hydroxy-n-butyl group, hydroxy-i-butyl group, hydroxy-sec-butyl group, and hydroxy-tert-butyl group.

The total number of carbon atoms in a molecule of the quaternary ammonium salt represented by Formula (8) is preferably 4 to 20, and more preferably 11 to 15 from viewpoints of water solubility and smooth etching of the silicon surface.

All of R¹¹¹, R¹¹², R¹¹³ and R¹¹⁴ may be the same group, and it is preferable that at least one of them is a different group. More preferably, at least one group of R¹¹¹, R¹¹², R¹¹³ and R¹¹⁴ is an alkyl group having 2 to 16 carbon atoms, and the remaining group is an alkyl group having 1 to 4 carbon atoms, still more preferably an alkyl group having 1 to 2 carbon atoms, and particularly preferably methyl group.

X represents a fluorine atom, a chlorine atom or a bromine atom, and preferably a chlorine atom or a bromine atom.

Specific preferable examples of the quaternary ammonium salt represented by Formula (8) include tetramethylammonium salt, tetraethylammonium salt, tetrapropylammonium salt, tetrabutylammonium salt, ethyltrimethylammonium salt, butyltrimethylammonium salt, hexyltrimethylammonium salt, octyltrimethylammonium salt, decyltrimethylammonium salt, dodecyltrimethylammonium salt, and tetradecyltrimethylammonium salt. Among these, octyltrimethylammonium salt, decyltrimethylammonium salt, or dodecyltrimethylammonium salt can be preferably used. These salts are chloride salts or bromide salts.

One kind of the quaternary ammonium salt represented by Formula (8) may be used alone, or a plurality of different kinds may be mixed and used.

The quaternary ammonium hydroxide represented by Formula (1) and the quaternary ammonium salt represented by Formula (8) may have the same quaternary ammonium cation.

The concentration of the quaternary ammonium salt represented by Formula (8) is not particularly limited, and the concentration of the quaternary ammonium salt represented by Formula (8) is preferably 1.0 mass % to 50 mass %, and more preferably 1.0 mass % to 25 mass % since even when the concentration of the quaternary ammonium hydroxide represented by Formula (1) is low, the silicon surface can be etched smoothly without any roughness; specifically, surface roughness of a (100) plane of silicon is reduced, the pyramid-shaped hillock surrounded by the (111) plane is prevented, and thereby the smooth etching can be performed.

In order to improve smoothness of the silicon surface, it is important to bring an etching selection ratio (100/111) between the (100) plane and the (111) plane of silicon close to 1, and the smoothness can be improved by setting the etching selection ratio to 3.0 or less, preferably 2.5 or less, and still more preferably 2.2 or less.

When the etching solution contains the reducing compound, the polyhydroxy compound, and the quaternary ammonium salt represented by Formula (8), the etching solution may contain these alone or in combination.

In addition to the reducing compound, the quaternary ammonium salt represented by Formula (8) and/or the polyhydroxy compound, which are optionally added in addition to the organic alkali, a surfactant or the like may be added to the etching solution within a range that the object of the present invention is not impaired. However, the preferred etching solution is substantially composed of the reducing compound, the quaternary ammonium salt represented by Formula (8) and/or the polyhydroxy compound, which are optionally added in addition to the organic alkali, and other components such as a surfactant preferably have a content of 1 mass % or less, and are more preferably not contained. That is, all of the balance other than the organic alkali, and the optionally added reducing compound, quaternary ammonium salt represented by Formula (8) and/or polyhydroxy compound is preferably water, particularly ultrapure water in which amounts of metal impurities are reduced.

In the etching solution, the quaternary ammonium hydroxide represented by Formula (1) and the quaternary ammonium salt represented by Formula (8) are ionized and dissociated into a quaternary ammonium cation represented by Formula (1′),

R¹¹R¹²R¹³R¹⁴N⁺ (1′)

(in the formula, R¹¹, R¹², R¹³, and R¹⁴ are the same as those in Formula (1))

OH⁻, a quaternary ammonium cation represented by Formula (8′),

R¹¹¹R¹¹²R¹¹³R¹¹⁴N⁺ (8′)

(in the formula, R¹¹¹, R¹¹², R¹¹³, and R¹¹⁴ are the same as those in Formula (8))

and X⁻ (same as that in Formula (8)). Therefore, as viewed from another aspect, the etching solution used in the present invention is a silicon etching solution that contains the above ion species.

At this time, naturally, the quaternary ammonium cation represented by Formula (1′) has a concentration same as that of the quaternary ammonium hydroxide represented by Formula (1), and the quaternary ammonium cation represented by Formula (8′) and X⁻ have a concentration same as that of the quaternary ammonium salt represented by Formula (8). A composition of the silicon etching solution according to the present invention can be checked by analyzing and quantifying ionic components and concentrations thereof in the solution and performing conversion to the quaternary ammonium hydroxide represented by Formula (1) and the quaternary ammonium salt represented by Formula (8). The quaternary ammonium cation can be measured by liquid chromatography or ion chromatography, the OH⁻ ion can be measured by neutralization titration, and the X⁻ ion can be measured by ion chromatography.

(Method for Manufacturing Etching Solution)

A method for manufacturing the etching solution used in the present invention is not particularly limited. The organic alkali, water, the reducing compound and the polyhydroxy compound that are optionally added, and the like may be mixed and dissolved to a predetermined concentration. The organic alkali and the reducing compound and/or the polyhydroxy compound may be used as they are, or may be used as an aqueous solution.

The method for manufacturing the etching solution is not particularly limited as long as the dissolved oxygen concentration in the etching solution is 0.20 ppm or less. Examples of the method include a vacuum degassing method in which an organic alkali is mixed and dissolved with water to achieve a predetermined concentration to obtain an organic alkaline aqueous solution, and the organic alkaline aqueous solution is degassed under a vacuum or a reduced pressure to remove dissolved oxygen from the organic alkaline aqueous solution, a bubbling method in which an inert gas is blown into an organic alkaline aqueous solution to remove dissolved oxygen, and a reducing compound addition method in which a reducing compound is added to an organic alkaline aqueous solution to remove dissolved oxygen. The dissolved oxygen concentration may be set to 0.20 ppm or less by appropriately using each of these methods alone or these methods in combination. Among these, from the viewpoint of efficiently reducing the amount of the dissolved oxygen, a combination of the bubbling method and the reducing compound addition method or the reducing compound addition method alone is most preferable.

The dissolved oxygen concentration in the etching solution may be set to 0.20 ppm or less at any time. The concentration may be 0.20 ppm or less at the time of etching, and the etching solution according to the present invention manufactured and stored in advance with a dissolved oxygen concentration in 0.20 ppm or less may be used, or may be manufactured immediately before the etching. In addition, the etching may be performed while manufacturing the etching solution. For example, in the bubbling method, nitrogen may be used as the inert gas, and the bubbling method may be performed such that the dissolved oxygen concentration is 0.20 ppm or less. In the reducing compound addition method, the dissolved oxygen concentration can be set to 0.20 ppm or less only by preparing an organic alkaline aqueous solution containing the reducing compound. When the bubbling method and the reducing compound addition method are used in combination, the dissolved oxygen concentration is lowered by bubbling of the inert gas, and thus it is possible to reduce a decomposition rate, since the reducing compound quenches oxygen.

In the method for processing a substrate according to the present invention, the above etching solution is used to be brought into contact with a substrate including a silicon film and a silicon-germanium film to perform etching and the silicon film is selectively removed. The silicon film means a silicon single crystal film, a polysilicon film, and an amorphous silicon film. The silicon single crystal film includes a film formed by epitaxial growth. For example, in a device structure in which an oxide film and/or a nitride film is used as an insulating film and, a silicon film and a silicon-germanium films are alternately stacked, only silicon can be selectively removed from the device structure, so that a nanowire pattern structure for GAA using silicon-germanium can be prepared while the oxide film and/or the nitride film remains as the insulating film.

A substrate processing method according to a first embodiment of the present invention includes a substrate holding step of holding a substrate including a silicon film and a silicon-germanium film in a horizontal posture, and a processing solution supplying step of supplying an etching solution to a main surface of the substrate while rotating the substrate around a vertical rotation axis passing through a central portion of the substrate.

A substrate processing method according to a second embodiment of the present invention includes a substrate holding step of holding a plurality of substrates described above in an upright posture and a step of immersing the substrates in the upright posture in an etching solution stored in a processing tank.

A temperature of the etching solution during etching may be appropriately determined from a range of 20° C. to 95° C., and is preferably in a range of 35° C. to 90° C. considering a desired etching rate, a shape and a surface condition of silicon after the etching, productivity, and the like.

During the etching, in order to maintain the dissolved oxygen concentration at 0.20 ppm or less, the etching may be performed while performing degassing under a vacuum or a reduced pressure or while performing bubbling with an inert gas. When the etching solution contains the reducing compound, it is not always necessary to perform the degassing under a vacuum or a reduced pressure or the bubbling with an inert gas, and from the viewpoint of maintaining the dissolved oxygen concentration at 0.20 ppm or less or further lowering the dissolved oxygen concentration, it is preferable to perform the degassing under a vacuum or a reduced pressure or the bubbling with an inert gas.

In wet etching of silicon, an etching target may be simply immersed in the silicon etching solution, and an electrochemical etching method can also be used to apply a constant potential to the etching target.

A target to be etched according to the present invention is a substrate including a silicon film and a silicon-germanium film. The silicon film is a silicon single crystal, polysilicon, or amorphous silicon, but is not limited thereto. In the processing method according to the present invention, the silicon film is selectively etched from the above substrate to allow the silicon-germanium film remain. In addition to the silicon film and the silicon-germanium film, the substrate may include a silicon oxide film, a silicon nitride film, various metal films, and the like which are not targets to be etched. Examples of the substrate include a structure in which a silicon film and a silicon-germanium film are alternately stacked, a structure in which a silicon-germanium film, a silicon oxide film, a silicon nitride film are formed on a silicon single crystal, and silicon or polysilicon and silicon-germanium are further formed thereon, and a structure formed by patterning these films.

By the above processing method, the silicon device is obtained by allowing the silicon-germanium film remain.

### EXAMPLES

Hereinafter, the present invention is described in more detail with reference to Examples, but the present invention is not limited to these Examples.

### Example 1

<Etching Solution Preparation Method>

A composition comprising tetrapropylammonium hydroxide (TPAH) serving as the organic alkali represented by Formula (1), in which balance of water is in amount obtained by subtracting the mass of glucose as the reducing compound later added was placed in a PFA beaker, followed by heating for 30 minutes in a water bath at a solution temperature shown in Table 1 and then nitrogen bubbling at 0.2 L/min for 30 minutes while being heated in the water bath. In the middle of the nitrogen bubbling for 30 minutes, glucose serving as the reducing compound was added in the amount corresponding to the mass subtracted was added and completely dissolved within a bubbling time. At a timing when the nitrogen bubbling for 30 minutes was completed, an etching solution under a condition shown in Table 1 was prepared.

<Method for Evaluating Etching Selection Ratio Between Single Crystal Silicon (100 Plane) and Silicon-Germanium>

The etching solution was heated to the solution temperature shown in Table 1, 100 mL of the etching solution was prepared, and a substrate (silicon-germanium film) in which silicon-germanium was epitaxially grown on a silicon substrate having a size of 2 cm×1 cm was immersed therein for 10 minutes, whereby an etching rate at this temperature was calculated. During the etching, the nitrogen bubbling was continued at the flow rate shown in Table 1. An etching rate (R_{SiGe}) was obtained by measuring, with a spectroscopic ellipsometer, a film thickness of each substrate before and after etching, obtaining an etching amount of the silicon-germanium film from a difference in the film thickness before and after processing, and dividing the etching amount by an etching time. Similarly, a substrate (silicon (100 plane) film) in which silicon was epitaxially grown on a silicon-germanium substrate having a size of 2 cm×1 cm was immersed for 60 seconds, whereby an etching rate (R′₁₀₀) of the silicon (100 plane) film was measured, and an etching selection ratio (R′₁₀₀/R_{SiGe}) between the silicon (100 plane) film and a silicon-germanium film was measured. Results are shown in Table 2.

<Method for Evaluating Etching Selection Ratio Between Silicon Single Crystal Substrate (100 Plane) and (111 Plane)>

The etching solution was heated to the solution temperature shown in Table 1, and a silicon single crystal substrate (100 plane) having a size of 2 cm×2 cm was immersed in 100 mL of the etching solution for 60 minutes, whereby an etching rate of the silicon single crystal at this temperature was measured. The target silicon single crystal substrate is obtained by removing a natural oxide film with a chemical solution. During the etching, the nitrogen bubbling was continued at the flow rate shown in Table 1. An etching rate (R₁₀₀) was obtained by measuring a weight of the silicon single crystal substrate (100 plane) before and after etching the silicon single crystal substrate (100 plane), converting a difference in the weight before and after processing to an etching amount of the silicon single crystal substrate, and dividing the etching amount by an etching time. Similarly, a silicon single crystal substrate (111 plane) having a size of 2 cm×2 cm was immersed for 60 minutes, an etching rate (R₁₁₁) of the silicon single crystal at this temperature was measured, and an etching selection ratio (R₁₀₀/R₁₁₁) with respect to the silicon single crystal substrate (100 plane) was obtained. Results are shown in Table 2.

<Method for Evaluating Surface Roughness of Silicon Single Crystal Substrate (100 Plane)>

Under a condition same as in the etching of the silicon single crystal substrate (100 plane) in the above <Method for Evaluating Etching Selection Ratio between Silicon Single Crystal Substrate (100 Plane) and (111 Plane)>, a surface state of the silicon single crystal substrate (100 plane) after etching such that the etching amount was about 1 μm was visually observed and observed by using field-emission scanning electron microscope (FE-SEM observation), and was evaluated according to the following criteria. Results are shown in Table 2.

<Evaluation Criteria for Surface Roughness of Silicon Single Crystal Substrate (100 Plane)>

(Visual Observation)

5: no white turbidity can be seen on a wafer surface, and the surface is a mirror surface.

3: a slight white turbidity can be seen on the wafer surface, but the surface is a mirror surface.

1: the wafer surface is completely white and turbid, but the mirror surface remains.

0: the wafer surface is completely white and turbid, and the mirror surface is lost due to severe surface roughness.

(FE-SEM Observation)

Any three locations were selected at an observation magnification of 20,000 times, a 50 μm square was observed, and presence or absence of hillocks was examined.

5: no hillock is observed in an observation field of view.

3: a minute hillock is observed in the observation field of view.

0: a large number of hillocks are observed in the observation field of view.

<Method for Measuring Dissolved Oxygen Concentration in Etching Solution>

The etching solution was heated to the solution temperature shown in Table 1, and the etching solution immediately before the etching and after the etching of the silicon-germanium film in the above <Method for Evaluating Etching Selection Ratio between Single Crystal Silicon (100 Plane) and Silicon-Germanium> was measured using a fluorescent dissolved oxygen measurement sensor (manufactured by Hamilton Company). During the measurement, the nitrogen bubbling was continued at the flow rate shown in Table 1. Results are shown in Table 2.

<Evaluation for Selection Ratio Between Silicon Single Crystal and Silicon Oxide Film and Silicon Nitride Film>

The etching solution was heated to the solution temperature shown in Table 1, a silicon oxide film and a silicon nitride film were immersed in the etching solution for 10 minutes, and the etching rates of the silicon oxide film and the silicon nitride film at this temperature were measured. During the etching, the nitrogen bubbling was continued at the flow rate shown in Table 1. The etching rates were obtained by measuring, with a spectroscopic ellipsometer, the film thicknesses before and after the etching of the silicon oxide film and the silicon nitride film, converting differences of the film thicknesses before and after the processing to etching amounts of the silicon oxide film and the silicon nitride film, and dividing each of the etching amounts by an etching time. Next, the etching selection ratio (R′₁₀₀/silicon oxide film) and (R′₁₀₀/silicon nitride film) of the etching rate (R′₁₀₀) with respect to the silicon (100) film obtained in the above <Method for Evaluating Etching Selection Ratio between Single Crystal Silicon (100 Plane) and Silicon-Germanium> were calculated and evaluated according to the following criteria. Results are shown in Table 2.

<Evaluation Criteria for Selection Ratio Between Silicon Single Crystal and Silicon Oxide Film and Silicon Nitride Film>

Selection ratios between silicon and the silicon oxide film (Si (100 plane)/SiO₂):

A: 1,000 or more, B: 700 or more and less than 1,000, C: 500 or more and less than 700, D: less than 500

Selection ratios between silicon single crystal and the silicon nitride film (Si (100 plane)/SiN)

A: 1,000 or more, B: 700 or more and less than 1,000, C: 500 or more and less than 700, D: less than 500

B and thereabove indicate good selectivity.

### Examples 2 to 46

An evaluation was performed in the same manner as in Example 1 except that an etching solution having the composition shown in Tables 1 and 3 were used as the etching solution. In an example using etching solution prepared without performing the nitrogen bubbling (a flow rate in the nitrogen bubbling was 0 L/min), the nitrogen bubbling was not performed during the etching. Results are shown in Tables 2 and 4.

### Comparative Examples 1 to 6

An evaluation was performed in the same manner as in Example 1 except that an etching solution having the composition shown in Table 1 was used as the etching solution. Results are shown in Table 2.

TABLE 1

| | | | | | | | | Nitrogen bubbling | |
|---|---|---|---|---|---|---|---|---|---|
| | | | | | | | | | Gas |
| | Etching solution | | | | | | Processing | Flow | flow |
| | Organic | Content | Reducing | Content | Polyhydroxy | Content | temperature | rate | time |
| | alkali | (mol/L) | compound | (mass %) | compound | (mass %) | (° C.) | (L/min) | (min) |
| Example 1 | TPAH | 0.26 | Glucose | 1 | — | — | 40 | 0.2 | 30 |
| Example 2 | TPAH | 0.26 | Glucose | 0.1 | — | — | 40 | 0 | 0 |
| Example 3 | TPAH | 0.26 | Glucose | 0.4 | — | — | 40 | 0 | 0 |
| Example 4 | TPAH | 0.26 | Glucose | 1 | — | — | 40 | 0 | 0 |
| Example 5 | TPAH | 1.04 | Glucose | 1 | — | — | 40 | 0 | 0 |
| Example 6 | TPAH | 0.26 | Glucose | 10 | — | — | 40 | 0 | 0 |
| Example 7 | TPAH | 0.26 | Glucose | 30 | — | — | 40 | 0 | 0 |
| Example 8 | TMAH | 0.26 | Fructose | 5 | — | — | 40 | 0 | 0 |
| Example 9 | TPAH | 0.26 | Maltose | 1 | — | — | 40 | 0 | 0 |
| Example 10 | TPAH | 0.26 | Galactose | 30 | — | — | 40 | 0 | 0 |
| Example 11 | TPAH | 0.26 | Hydroxylamine | 1 | — | — | 40 | 0.2 | 30 |
| Example 12 | TPAH | 0.26 | Diethylhydroxylamine | 5 | — | — | 40 | 0.2 | 30 |
| Example 13 | TPAH | 0.26 | Hydrazine | 5 | — | — | 40 | 0.2 | 30 |
| Example 14 | TPAH | 0.26 | Carbohydrazide | 5 | — | — | 40 | 0.2 | 30 |
| Example 15 | 2-Amino-2-methyl-2- | 0.26 | Maltose | 2 | — | — | 40 | 0.2 | 30 |
| | propanol | | | | | | | | |
| Example 16 | Diethylenetriamine | 0.26 | Maltose | 2 | — | — | 40 | 0.2 | 30 |
| Example 17 | Ethylenedamine | 0.26 | Maltose | 2 | — | — | 40 | 0.2 | 30 |
| Example 18 | 2-(2- | 0.26 | Maltose | 2 | — | — | 40 | 0.2 | 30 |
| | Aminoethoxy)ethanol | | | | | | | | |
| Example 19 | Choline hydroxide | 0.26 | Maltose | 2 | — | — | 40 | 0.2 | 30 |
| Example 20 | TPAH | 0.26 | Glucose | 20 | Ethylene glycol | 20 | 40 | 0 | 0 |
| Example 21 | TMAH | 0.26 | Glucose | 1 | Ethylene glycol | 40 | 40 | 0 | 0 |
| Example 22 | TPAH | 0.26 | Glucose | 1 | Ethylene glycol | 60 | 40 | 0 | 0 |
| Example 23 | TPAH | 0.26 | Maltose | 0.5 | Ethylene glycol | 60 | 40 | 0 | 0 |
| Example 24 | TPAH | 0.26 | Maltose | 1 | Ethylene glycol | 60 | 40 | 0 | 0 |
| Example 25 | TMAH | 0.26 | Galactose | 0.1 | Ethylene glycol | 40 | 40 | 0.2 | 30 |
| | | | | | glycerin | 20 | | | |
| Example 26 | TPAH | 0.26 | Glucose | 0.1 | Ethylene glycol | 40 | 40 | 0.2 | 30 |
| | | | | | glycerin | 20 | | | |
| Example 27 | TPAH | 0.26 | Glucose | 1 | Ethylene glycol | 40 | 40 | 0.2 | 30 |
| | | | | | glycerin | 20 | | | |
| Example 28 | TPAH | 0.26 | Glucose | 1 | Ethylene glycol | 40 | 40 | 0 | 0 |
| | | | | | glycerin | 20 | | | |
| Example 29 | TMAH | 0.26 | Galactose | 0.1 | Ethylene glycol | 75 | 40 | 0.2 | 30 |
| Example 30 | TPAH | 0.26 | Maltose | 0.3 | Ethylene glycol | 75 | 40 | 0 | 0 |
| Comparative | KOH | 3.08 | — | — | — | — | 40 | 0.2 | 30 |
| Example 1 | | | | | | | | | |
| Comparative | TMAH | 0.26 | — | — | — | — | 40 | 0.2 | 30 |
| Example 2 | | | | | | | | | |
| Comparative | ETMAH | 0.26 | — | — | — | — | 40 | 0.2 | 30 |
| Example 3 | | | | | | | | | |
| Comparative | TEAH | 0.26 | — | — | — | — | 40 | 0.2 | 30 |
| Example 4 | | | | | | | | | |
| Comparative | TPAH | 0.26 | — | — | — | — | 40 | 0.2 | 30 |
| Example 5 | | | | | | | | | |
| Comparative | TBAH | 0.26 | — | — | — | — | 40 | 0.2 | 30 |
| Example 6 | | | | | | | | | |

TABLE 2

| | Dissolved | | Si(100)/SiGe | | | Si(100/111) | | |
|---|---|---|---|---|---|---|---|---|
| | oxygen (ppm) | | etching | Surface state | | etching | | |
| | Immediately | | selection | evaluation * | | selection | Selection ratio | |
| | before | After | ratio | Visual | FE-SEM | ratio | evaluation (A to E) | |
| | etching | etching | (R′₁₀₀/R_{SiGe}) | evaluation | evaluation | (R₁₀₀/R₁₁₁) | Si/SiO₂ | Si/SiN |
| Example 1 | <0.05 | <0.05 | 210 | 5 | 5 | 2.4 | A | A |
| Example 2 | 0.15 | 0.14 | 70 | 5 | 5 | 2.3 | A | A |
| Example 3 | 0.10 | 0.09 | 90 | 5 | 5 | 2.3 | A | A |
| Example 4 | <0.05 | <0.05 | 190 | 5 | 5 | 2.5 | A | A |
| Example 5 | <0.05 | <0.05 | 210 | 1 | 0 | 3.0 | A | A |
| Example 6 | <0.05 | <0.05 | 240 | 3 | 5 | 2.6 | A | A |
| Example 7 | <0.05 | <0.05 | 200 | 3 | 5 | 2.8 | A | A |
| Example 8 | <0.05 | <0.05 | 250 | 0 | 0 | 6.4 | A | A |
| Example 9 | <0.05 | <0.05 | 250 | 3 | 5 | 2.8 | A | A |
| Example 10 | <0.05 | <0.05 | 190 | 1 | 0 | 3.2 | A | A |
| Example 11 | <0.05 | <0.05 | 190 | 3 | 5 | 2.7 | A | A |
| Example 12 | <0.05 | <0.05 | 100 | 3 | 5 | 2.6 | A | A |
| Example 13 | <0.05 | <0.05 | 140 | 1 | 0 | 3.9 | A | A |
| Example 14 | <0.05 | <0.05 | 130 | 3 | 5 | 2.9 | A | A |
| Example 15 | <0.05 | <0.05 | 320 | 0 | 0 | 9.1 | A | A |
| Example 16 | <0.05 | <0.05 | 170 | 1 | 0 | 3.5 | A | A |
| Example 17 | <0.05 | <0.05 | 200 | 0 | 0 | 8.3 | A | A |
| Example 18 | <0.05 | <0.05 | 310 | 0 | 0 | 8.8 | A | A |
| Example 19 | <0.05 | <0.05 | 210 | 0 | 0 | 6.7 | A | A |
| Example 20 | <0.05 | <0.05 | 250 | 5 | 5 | 2.0 | A | A |
| Example 21 | <0.05 | <0.05 | 220 | 5 | 5 | 2.2 | A | A |
| Example 22 | <0.05 | <0.05 | 260 | 5 | 5 | 2.1 | A | A |
| Example 23 | <0.05 | <0.05 | 340 | 5 | 5 | 1.8 | A | A |
| Example 24 | <0.05 | <0.05 | 350 | 5 | 5 | 2.2 | A | A |
| Example 25 | <0.05 | <0.05 | 130 | 5 | 5 | 1.4 | A | A |
| Example 26 | <0.05 | <0.05 | 100 | 5 | 5 | 1.3 | A | A |
| Example 27 | <0.05 | <0.05 | 250 | 5 | 5 | 2.1 | A | A |
| Example 28 | <0.05 | <0.05 | 220 | 5 | 5 | 2.2 | A | A |
| Example 29 | <0.05 | <0.05 | 110 | 5 | 5 | 1.4 | A | A |
| Example 30 | <0.05 | <0.05 | 140 | 5 | 5 | 1.4 | A | A |
| Comparative | 0.25 | 0.25 | 50 | 0 | 0 | 7.0 | D | D |
| Example 1 | | | | | | | | |
| Comparative | 0.25 | 0.25 | 50 | 1 | 0 | 3.6 | A | A |
| Example 2 | | | | | | | | |
| Comparative | 0.25 | 0.25 | 50 | 1 | 0 | 3.4 | A | A |
| Example 3 | | | | | | | | |
| Comparative | 0.25 | 0.25 | 40 | 1 | 0 | 4.0 | A | A |
| Example 4 | | | | | | | | |
| Comparative | 0.25 | 0.25 | 50 | 5 | 5 | 2.2 | A | A |
| Example 5 | | | | | | | | |
| Comparative | 0.25 | 0.25 | 10 | 5 | 5 | 2.0 | A | A |
| Example 6 | | | | | | | | |

* Visual evaluation (5, 3, 1, 0), FE-SEM evaluation (5, 3, 0)

TABLE 3

| | Etching solution | | | | | | | |
|---|---|---|---|---|---|---|---|---|
| | | | | | | | Quatemary ammonium salt | |
| | | Content | Reducing | Content | Polyhydroxy | Content | (compound represented by | Content |
| | Organic alkali | (mol/L) | compound | (mass %) | compound | (mass %) | Formula (8)) | (mass %) |
| Example | Piperidine | 0.26 | Maltose | 3 | | | | |
| 31 | | | | | | | | |
| Example | Pyrrolidine | 0.26 | Maltose | 3 | | | | |
| 32 | | | | | | | | |
| Example | 1,1,3,3-Tetramethylguanidine | 0.26 | Galactose | 3 | | | | |
| 33 | | | | | | | | |
| Example | 1,8-Diazabicydo[5.4.0]undec- | 0.26 | Arabinose | 3 | | | | |
| 34 | 7-ene | | | | | | | |
| Example | 1,5-Diazabicydo[4.3.0]non- | 0.26 | Arabinose | 3 | | | | |
| 35 | 5-ene | | | | | | | |
| Example | 1,4-Diaminobutane | 0.26 | Ribose | 3 | | | | |
| 36 | | | | | | | | |
| Example | 1,5-Diaminopentane | 0.26 | Ribose | 3 | | | | |
| 37 | | | | | | | | |
| Example | 1,6-Diaminohexane | 0.26 | Ribose | 1 | | | | |
| 38 | | | | | | | | |
| Example | 1,8-Diaminooctane | 0.26 | Ribose | 1 | | | | |
| 39 | | | | | | | | |
| Example | Dipropylenetriamine | 0.26 | Galactooligo- | 3 | | | | |
| 40 | | | saccharide | | | | | |
| Example | Bis(hexamethylene)triamine | 0.26 | Maltose | 1 | | | | |
| 41 | | | | | | | | |
| Example | Bis(hexamethylene)triamine | 0.78 | Maltose | 3 | | | | |
| 42 | | | | | | | | |
| Example | N,N-bis(3- | 0.26 | Erythrose | 0.5 | | | | |
| 43 | aminopropyl)ethylenediamine | | | | | | | |
| Example | TPAH | 0.26 | Maltose | 1 | | | Octyltrimethylammonium | 5 |
| 44 | | | | | | | bromide | |
| Example | TPAH | 0.26 | Ribose | 3 | | | Decyltrimethylammonium | 1.5 |
| 45 | | | | | | | chloride | |
| Example | TMAH | 0.26 | Glucose | 1 | Ethylene | 40 | Dodecyltrimethylammonium | 1 |
| 46 | | | | | glycol | | bromide | |

TABLE 4

| | | Nitrogen bubbling | | Dissolved | | | | | Si(100/111) | | |
|---|---|---|---|---|---|---|---|---|---|---|---|
| | | | Gas | oxygen (ppm) | | Si(100)/SiGe | Surface state | | etching | | |
| | Processing | Flow | flow | Immediately | | etching | evaluation* | | selection | Selection ratio | |
| | temperature | rate | time | before | After | selection ratio | Visual | FE-SEM | ratio | evaluation (A to E) | |
| | (° C.) | (L/min) | (min) | etching | etching | (R'₁₀₀/R_{SiGe}) | evaluation | evaluation | (R₁₀₀/R₁₁) | Si/SiO₂ | Si/SiN |
| Example 31 | 40 | 0.2 | 30 | <0.05 | <0.05 | 460 | 3 | 5 | 2.8 | A | A |
| Example 32 | 40 | 0.2 | 30 | <0.05 | <0.05 | 500 | 1 | 0 | 3.8 | A | A |
| Example 33 | 40 | 0.2 | 30 | <0.05 | <0.05 | 470 | 1 | 0 | 3.8 | A | A |
| Example 34 | 40 | 0.2 | 30 | <0.05 | <0.05 | 460 | 3 | 5 | 2.9 | A | A |
| Example 35 | 40 | 0.2 | 30 | <0.05 | <0.05 | 750 | 1 | 0 | 3.9 | A | A |
| Example 36 | 40 | 0.2 | 30 | <0.05 | <0.05 | 580 | 1 | 0 | 3.2 | A | A |
| Example 37 | 40 | 0.2 | 30 | <0.05 | <0.05 | 730 | 1 | 0 | 3.0 | A | A |
| Example 38 | 40 | 0.2 | 30 | <0.05 | <0.05 | 990 | 3 | 5 | 2.8 | A | A |
| Example 39 | 40 | 0.2 | 30 | <0.05 | <0.05 | 770 | 5 | 5 | 2.0 | A | A |
| Example 40 | 40 | 0.2 | 30 | <0.05 | <0.05 | 620 | 3 | 5 | 2.7 | A | A |
| Example 41 | 40 | 0.2 | 30 | <0.05 | <0.05 | 890 | 5 | 5 | 2.1 | A | A |
| Example 42 | 40 | 0.2 | 30 | <0.05 | <0.05 | 1030 | 5 | 5 | 2.3 | A | A |
| Example 43 | 40 | 0.2 | 30 | <0.05 | <0.05 | 950 | 5 | 5 | 2.1 | A | A |
| Example 44 | 40 | 0.2 | 30 | <0.05 | <0.05 | 200 | 5 | 5 | 2.3 | A | A |
| Example 45 | 40 | 0.2 | 30 | <0.05 | <0.05 | 210 | 5 | 5 | 2.2 | A | A |
| Example 46 | 40 | 0.2 | 30 | <0.05 | <0.05 | 150 | 5 | 5 | 1.9 | A | A |

*Visual evaluation (5, 3, 1, 0), FE-SEM evaluation (5, 3, 0)

In order to check a difference between an etching solution using a reducing sugar having a hydroxy group on 2-position carbon as the reducing compound and an etching solution using a reducing sugar having no hydroxy group on 2-position carbon as the reducing compound, the following Example A and Example B were performed. Physical properties in Example A and Example B are evaluated by the following method.

(1) pH

After preparation of the etching solution, the etching solution was stored at a predetermined temperature for a predetermined time, and pH measurement was performed using a desktop pH meter (LAQUA F-73, manufactured by HORIBA, Ltd.). The pH measurement was performed after the solution temperature was stabilized at 25° C.

(2) Si Etching Rate and Etching Selection Ratio Between Si and SiGe

An etching solution (100 mL) heated to a predetermined solution temperature was prepared, and a substrate (silicon (100 plane) film) in which silicon was epitaxially grown on a silicon-germanium substrate having a size of 2 cm×1 cm was immersed therein for 20 seconds. During the etching, the solution was stirred at 1,200 rpm, and the nitrogen bubbling was continuously performed at 0.2 L/min. The etching rate (R′₁₀₀) was obtained by measuring, with a spectroscopic ellipsometer, a film thickness of each substrate before and after etching, obtaining an etching amount of the silicon film from a difference in the film thickness before and after processing, and dividing the etching amount by an etching time to measure an etching rate of the silicon (100 plane) film at this temperature.

Similarly, a substrate (silicon-germanium film) in which silicon-germanium was epitaxially grown on a silicon substrate having a size of 2 cm×1 cm was immersed for 10 minutes, whereby an etching rate (R_{SiGe}) at this temperature was calculated.

From these measurement results, the etching selection ratio (R′₁₀₀/R_{SiGe}) between the silicon (100 plane) film and the silicon-germanium film was obtained.

### Example A

A heating temperature was set to 43° C., a heating time was set to 1 h to 9 h, and an etching solution composed of an aqueous solution containing 1,1,3,3-tetramethylguanidine (TMG) as an organic alkaline compound at a concentration of 0.26 mol/L and D-maltose having a hydroxy group on 2-position carbon as a reducing sugar at a concentration of 5.0 mass % was prepared.

A pH and an etching selection ratio between Si and SiGe were evaluated for this etching solution. The etching was also performed at a solution temperature of 43° C. Results are shown in Table 5.

As shown in Table 5, the etching solution has a high initial pH (1 h), exhibits a good Si etching rate, and has a selection ratio higher due to an effect of added maltose. However, at a timing of storing at 43° C. for 9 hours, the selection ratio remains good, and the pH is decreased by about 1, and the etching rate is decreased to about half. The etching selection ratio (R′₁₀₀₊/R_{SiGe}) is high, but it is considered that the etching solution is not sufficient for industrial production repeatedly using the etching solution for a long time.

### Example B

Similarly to Example A, a heating temperature was set to 43° C., a heating time was set to 1 h to 9 h, and an etching solution composed of an aqueous solution containing TMG at a concentration of 0.26 mol/L as an organic alkaline compound and N-acetyl-D-glucosamine having no hydroxy group on the 2-position carbon at a concentration of 3.22 mass % as a reducing sugar was prepared. The N-acetylglucosamine is set to 3.22 mass % to have a concentration same as 5.0 mass % of maltose on a molar basis.

A pH and an etching selection ratio between Si and SiGe were evaluated for this etching solution. Results are also shown in Table 5.

As shown in Table 5, an initial etching rate of Si in the etching solution is slightly lower than that in Example A, whereas the pH after storage at 43° C. for 9 hours does not greatly decrease from an initial value, and the etching rate of Si is maintained at a rate close to 80% of an initial rate. Therefore, it is considered to be used industrially much easier than that in Comparative Examples.

TABLE 5

| | Organic | | | Heating time | | |
|---|---|---|---|---|---|---|
| | alkaline | Reducing | Evaluation | at 43° C. | | |
| | compound | sugar | item | 1 hr | 3 hr | 9 hr |
| Exam- | TMG | Maltose | pH | 12.4 | 11.9 | 11.4 |
| ple A | | | Si etching rate | 62 | 54 | 33 |
| | | | (nm/min) | | | |
| | | | Si/SiGe etching | 718 | 668 | 658 |
| | | | selection ratio | | | |
| Exam- | TMG | N-acetyl | pH | 12.7 | 12.7 | 12.5 |
| ple B | | glucosamine | Si etching rate | 44 | 47 | 35 |
| | | | (nm/min) | | | |
| | | | Si/SiGe etching | 310 | 339 | 256 |
| | | | selection ratio | | | |

1. A method for processing a substrate comprising:
bringing an etching solution into contact with a substrate including a silicon film and a silicon-germanium film to perform etching; and
selectively removing the silicon film, wherein
the etching solution contains an organic alkali and water and has a dissolved oxygen concentration of 0.20 ppm or less.

2. The method for processing a substrate according to claim 1, wherein
the etching solution contains a reducing compound.

3. The method for processing a substrate according to claim 2, wherein
the reducing compound is at least one selected from the group consisting of hydrazines, hydroxylamines, a reducing sugar, and gallic acid.

4. The method for processing a substrate according to claim 2, wherein
the reducing compound is a reducing sugar having no hydroxy group on 2-position carbon.

5. The method for processing a substrate according to claim 1, wherein
a concentration of the organic alkali contained in the etching solution is 0.05 mol/L to 2.2 mol/L.

6. A method for manufacturing a silicon device comprising:
the method for processing a substrate according to claim 1.
